(19) United States
(12) Patent Application Publication
(10) Pub. No.: US 2008/0157135 A1
(43) Pub. Date: Jul. 3, 2008

(54) CMOS IMAGE SENSOR AND METHOD OF MANUFACTURING THEREOF

(76) Inventor: Keun-Hyuk Lim, Seoul (KR)

Correspondence Address: SHERR & NOURSE, PLLC, 620 HERNDON PARKWAY, SUITE 200, HERNDON, VA, 20170, US

(21) Appl. No.: 11/963,339

(22) Filed: Dec. 21, 2007

(30) Foreign Application Priority Data
Dec. 29, 2006 (KR) 10-2006-0137343

(51) Int. Cl. H01L 27/146; H01L 31/18

(52) U.S. Cl. 257/290; 438/59; 257/E27.133

(57) ABSTRACT

A CMOS image sensor and a method of manufacturing thereof is capable of preventing a feed-through phenomenon. A CMOS image sensor includes a reset transistor which may include an epi-layer formed over a semiconductor substrate. The reset transistor also includes a channel layer formed over the epi-layer to form a channel. A trap area may be formed in a central portion of the reset transistor. A gate electrode may be formed over the epi-layer with a gate insulating film interposed therebetween. A gate spacer may be formed over both sidewalls of the gate electrode. A diffusion area may be formed at both sides of the gate spacer.

The present application claims priority under 35 U.S.C. 119 to Korean Patent Application No. 10-2006-0137343, filed on Dec. 29, 2006, which is hereby incorporated by reference in its entirety.

### BACKGROUND

An image sensor converts an optical image into an electrical signal. Image sensors may be classified as complementary metal-oxide-silicon (CMOS) image sensors or charge coupled device (CCD) image sensors. The CCD image sensor has better photosensitivity and lower noise compared with the CMOS image sensor. However, CCD image sensors may be more difficult to fabricate into highly integrated devices and have higher power consumption.

In contrast, compared with CCD image sensors, CMOS image sensors have a simpler manufacturing process, higher integration, and lower power consumption. Recently, as technology for manufacturing semiconductor devices has advanced, technology for manufacturing CMOS image sensors has advanced. Pixels of the CMOS image sensor may include photodiodes for receiving light and transistors for controlling image signals input through the photodiodes. CMOS image sensors may be divided into a 3T type, a 4T type, or a 5T type depending on the number of transistors. A 3T type CMOS image sensor includes a photodiode and three transistors while the 4T type CMOS image sensor includes a photodiode and four transistors.

FIG. 1 shows a plan view showing a related CMOS image sensor. Referring to FIG. 1, a 4T type CMOS image sensor includes a photodiode area PD, a transfer transistor Tₓ, a reset transistor Rₓ, and a drive transistor Dₓ. The photodiode area PD is formed in the widest portion of an active area 1. The transfer transistor Tₓ, the reset transistor Rₓ, and the drive transistor Dₓ are formed to overlap the active area 1 excluding the photodiode area PD. A selection transistor Sₓ may be included to bring the total number of transistors to four per photodiode.

The photodiode PD detects incident light and generates charges according to the intensity of light. The transfer transistor Tₓ carries the charges generated at the photodiode PD to a floating diffusion area FD. Before carrying the charges, the floating diffusion area FD moves electrons received from the photodiodes PD to the reset transistor Tx to turn on the reset transistor Rₓ. Accordingly, the floating diffusion area FD may be set to a predetermined low charge state.

The reset transistor Rₓ discharges the charges stored in the floating diffusion area FD, in order to detect a signal. The drive transistor Dₓ functions as a source follower for converting the charges received from the photodiodes PD into a voltage signal.

As shown in FIG. 2, the reset transistor Rₓ may include a P-type epi-layer 4, a P-type channel layer 6, a gate electrode 10, a gate spacer 12, and an n+-type diffusion area 14. The P-type epi-layer 4 is formed over a P++-type semiconductor substrate 2. The P-type channel layer 6 is formed over the epi-layer 4 to form a channel. The gate electrode 10 is formed over the P-type channel layer 6 with a gate insulating film 8 interposed therebetween. The gate spacer 12 is formed over both sidewalls of the gate electrode 10. The n+-type diffusion area 14 is formed by implanting dopant ions into the epi-layer 4 located at both sides of the gate spacer 12. The reset transistor Rₓ is connected between the floating diffusion area FD and a power supply voltage V_{dd}.

As shown in FIG. 3, when the reset transistor Rₓ is turned on, electrons stored in the floating diffusion area FD are discharged to the power supply voltage V_{dd}. In contrast, as shown in FIG. 4, when the reset transistor Rₓ is turned off, the reset transistor Rx blocks electrons stored in the floating diffusion area FD from being discharged to the power supply voltage V_{dd}.

A voltage across the floating diffusion area FD is expressed by Equation 1.

V_{FD}=V_{dd}−Vₜₕ Equation 1

where, V_{FD} denotes the voltage across the floating diffusion area FD and Vₜₕ denotes a threshold voltage of the reset transistor Rₓ.

When the reset transistor Rₓ is turned off, a problem occurs when electrons included in a channel area located below the gate electrode of the reset transistor Rₓ flow into the floating diffusion area FD and the power supply voltage V_{dd}. This causes the voltage across the floating diffusion area FD to drop. This phenomenon is called a feed-through phenomenon. Due to the feed-through phenomenon, the electrons are not evenly divided, and may instead be randomly divided. Accordingly, the voltage across the floating diffusion area FD is not maintained constant. As a result, operation of the photodiode may become non-uniform.

### SUMMARY

Embodiments relate to a CMOS image sensor capable of preventing a feed-through phenomenon and a method of manufacturing thereof. Embodiments relate to a CMOS image sensor which includes a reset transistor which may includes an epi-layer formed over a semiconductor substrate. The reset transistor also includes a channel layer formed over the epi-layer to form a channel. A trap area may be formed in a central portion of the reset transistor. A gate electrode may be formed over the epi-layer with a gate insulating film interposed therebetween. A gate spacer may be formed over both sidewalls of the gate electrode. A diffusion area may be formed at both sides of the gate spacer.

Embodiments relate to a method of manufacturing a CMOS image sensor including a reset transistor that includes forming an epi-layer over a semiconductor substrate. A channel layer may be formed over the epi-layer to form a channel. A photoresist pattern may be formed for exposing the channel layer of a central portion of the reset transistor. N-type dopant ions may be implanted into the exposed channel layer and epi-layer to form a trap area. A gate insulating film may be formed over the channel layer in which the trap area is formed. A gate electrode may be formed over the gate insulating film. A gate spacer may be formed over both sidewalls of the gate electrode. N+-type dopant ions may be implanted into the epi-layer located at both sides of the gate spacer to form a diffusion area.

### DRAWINGS

FIG. 1 is a plan view showing a related CMOS image sensor.

FIG. 2 is a cross-sectional view taken along line A-A′ of the CMOS image sensor shown in FIG. 1.

FIG. 3 is a view showing migration of electrons when a reset transistor shown in FIG. 2 is turned on.

FIG. 4 is a view showing migration of electrons when a reset transistor shown in FIG. 2 is turned off.

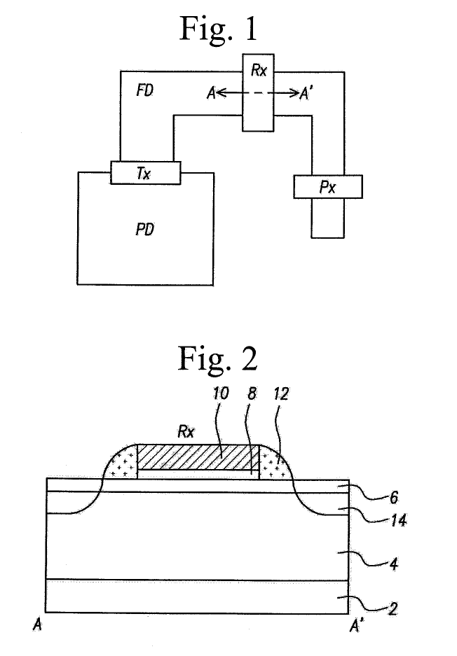

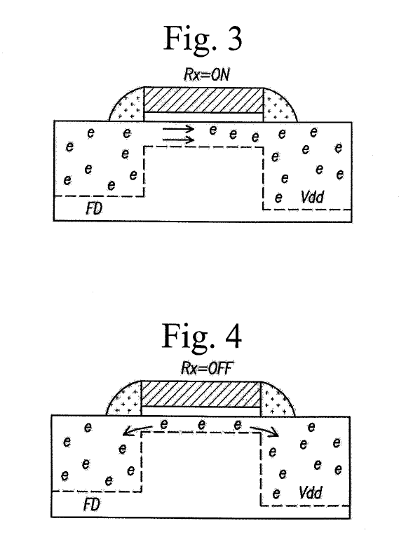

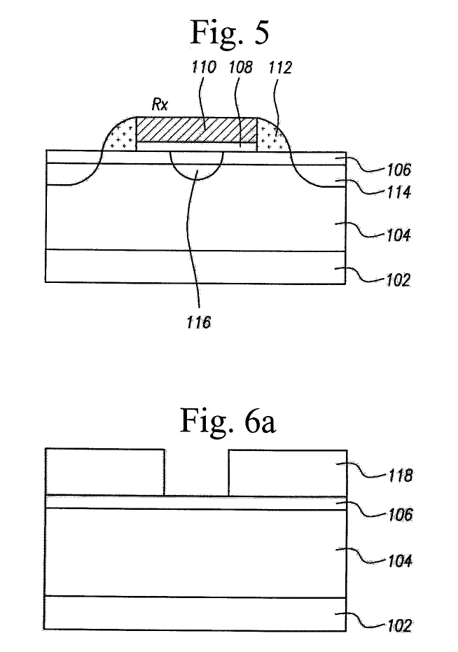

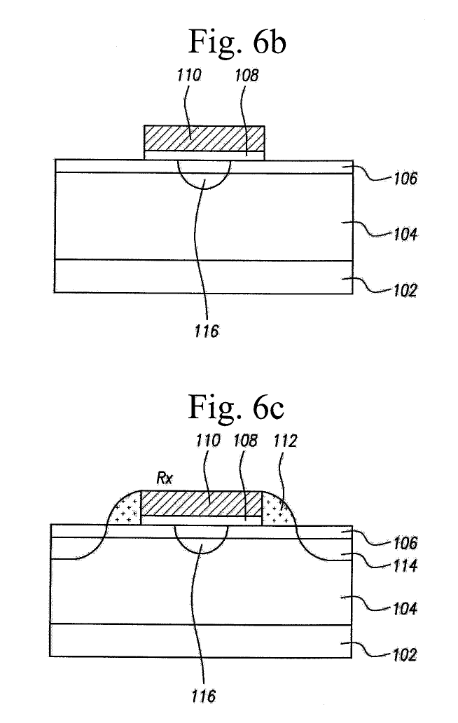

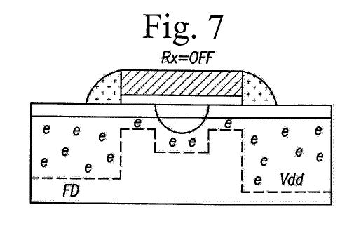

Example FIG. 5 is a cross-sectional view showing a CMOS image sensor according to embodiments.

Example FIGS. 6A to 6C are views showing a method of manufacturing the CMOS image sensor shown in example FIG. 5.

Example FIG. 7 is a view showing the migration and potential of electrons when the reset transistor shown in example FIG. 5 is turned off.

### DESCRIPTION

Example FIG. 5 is a cross-sectional view showing a CMOS image sensor according to embodiments. Referring to example FIG. 5, the CMOS image sensor according to embodiments includes a reset transistor Rₓ. The reset transistor Rₓ may include a P-type epi-layer 104, a P-type channel layer 106, a trap area 116, a gate electrode 110, a gate spacer 112, and an n+-type diffusion area 114. The P-type epi-layer 104 may be formed over a P++-type semiconductor substrate 102. The P-type channel layer 106 may be formed over the epi-layer 104 to form a channel. The trap area 116 may be formed by implanting an n-type dopant into the epi-layer 104 and the channel layer 106 in a central portion of the reset transistor Rₓ. The gate electrode 110 may be formed over the epi-layer 104 with a gate insulating film 108 interposed therebetween. The gate spacer 112 is formed over the sidewalls of the gate electrode 110. The n+-type diffusion area 114 may be formed by implanting dopant ions into the epi-layer 104 at the sides of the gate spacer 112.

The reset transistor Rx having the above-described configuration is located between a floating diffusion area FD and a power supply voltage V_{dd} to be connected to the floating diffusion area FD and the power supply voltage V_{dd}. When the reset transistor Rₓ is turned on, the reset transistor Rₓ discharges electrons stored in the floating diffusion area FD to the power voltage supply area V_{dd}. In contrast, when the reset transistor Rₓ is turned off, the reset transistor Rₓ blocks the electrons stored in the floating diffusion area FD from being discharged to the power supply voltage V_{dd}.

Example FIGS. 6A to 6C are views showing a method of manufacturing a CMOS image sensor shown in example FIG. 5. As shown in example FIG. 6A, an epi-layer 104, a channel layer 106 and a photoresist pattern 118 are formed over a semiconductor substrate 102. An epitaxial process may be performed over the high-concentration P++-type semiconductor substrate 102 to form a low-concentration P-type epi-layer 104. The P-type channel layer 106 for forming a channel may be formed over the epi-layer 104. Next, the photoresist pattern 118 for exposing the channel layer 106 corresponding to a central potion of a reset transistor Rₓ may be formed. Here, the width of the exposed channel layer 106 may be approximately 0.1 μm to 0.15 μm.

Thereafter, as shown in FIG. 6B, n-type dopant ions may be implanted into the exposed channel layer 106 and epi-layer 104 using the photoresist pattern 118 as a mask to form a trap area 116. The depth of the trap area 116 may be larger than that of the channel layer 106. That is, the trap area 116 may have a depth of approximately 20 to 80 nm and the channel layer 106 may have a depth of approximately 20 to 50 nm.

Next, a gate insulating film 108 and a gate electrode 110 may be formed over the channel layer 106 in which the trap area 116 is formed. In particular, a gate insulating film and a gate metal layer may be formed over the channel layer 106 using a deposition method. Subsequently, the gate insulating film and the gate metal layer may be patterned by a photolithography process using a mask to form the gate insulating film 108 and the gate electrode 110.

As shown in example FIG. 6C, a gate spacer 112 may be formed over the sidewalls of the gate electrode 110. In particular, an insulating film (SiN) may be formed over the gate electrode 110 and an etch-back process may be performed to form the gate spacer 112 over the sidewalls of the gate electrode 110.

An operation of the reset transistor Rx will be described with reference to example FIG. 7. Example FIG. 7 is a view showing the migration and the potential of electrons when the reset transistor shown in example FIG. 5 is turned off. The reset transistor Rₓ is connected between the floating diffusion area FD and the power supply voltage V_{dd}. When the reset transistor Rₓ is turned on, the reset transistor Rx discharges the electrons stored in the floating diffusion area FD to the power supply voltage V_{dd}.

In contrast, as shown in FIG. 7, when the reset transistor Rₓ is turned off, the reset transistor Rₓ blocks the electrons stored in the floating diffusion area FD from being discharged to the power supply voltage V_{dd}. The trap area 116 formed in the central portion of the reset transistor Rₓ blocks the electrons included in the channel area of the reset transistor Rₓ from flowing into the floating diffusion area FD and the power supply voltage V_{dd}.

According to embodiments, it is possible to prevent the voltage across the floating diffusion area FD from dropping and to prevent a feed-through phenomenon. As a result, the voltage across the floating diffusion area FD may be maintained constant and thus operations of a photodiode may be made more uniform. A reset transistor Rₓ according to embodiments is also applicable to 3T type CMOS image sensor.

As described above, in a CMOS image sensor and a method of manufacturing thereof according to embodiments, a trap area is formed by implanting an n-type dopant into a central channel area of a reset transistor Rx. Accordingly, it is possible to block electrons included in the channel area of the reset transistor Rₓ from flowing into the floating diffusion area FD and the power supply voltage V_{dd}. As a result, in the CMOS image sensor and the method of manufacturing thereof according to embodiments, it is possible to prevent the voltage across the floating diffusion area FD from substantially dropping and to prevent a feed-through phenomenon. Therefore, in the CMOS image sensor and the method of manufacturing thereof according to embodiments, it is possible to maintain a substantially constant voltage across the floating diffusion area FD such that operations of a photodiode can be made more uniform.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
an epi-layer formed over a semiconductor substrate;
a channel layer formed over the epi-layer;
a gate insulating film formed over the epi-layer;
a gate electrode formed over the gate insulating film;
a gate spacer formed over sidewalls of the gate electrode;
a diffusion area formed at both sides of the gate spacer; and
a trap area formed under a central portion of the gate.

2. The apparatus of claim 1, wherein the trap area has a width of approximately 0.1 μm to 0.15 μm.

3. The apparatus of claim 1, wherein a depth of the trap area is larger than that of the channel layer.

4. The apparatus of claim 1, wherein the trap area has a depth of approximately 20 nm to 80 nm.

5. The apparatus of claim 1, wherein the channel layer has a depth of approximately 20 nm to 50 nm.

6. The apparatus of claim 1, wherein the epi-layer is of a P-type.

7. The apparatus of claim 1, wherein the channel layer is of a P-type.

8. The apparatus of claim 1, wherein the trap area is formed by implanting n-type dopant ions into the epi-layer including the channel layer.

9. The apparatus of claim 1, wherein the diffusion area is formed by implanting n+-type dopant ions into the epi-layer located at sides of the gate spacer.

10. The apparatus of claim 1, wherein the trap area is formed in a central portion of a channel formed in the channel layer.

11. The apparatus of claim 1, wherein the epi-layer, channel layer, gate insulating film, gate electrode, gate spacer, diffusion area, and trap area form a reset transistor in a CMOS image sensor.

12. A method comprising:
forming an epi-layer over a semiconductor substrate;
forming a channel layer over the epi-layer to form a channel;
forming a photoresist pattern for exposing a portion of the channel layer;
implanting dopant ions into the exposed channel layer and epi-layer to form a trap area;
forming a gate insulating film over the channel layer in which the trap area is formed;
forming a gate electrode over the gate insulating film;
forming a gate spacer over both sidewalls of the gate electrode; and
implanting n-type ions into the epi-layer located at both sides of the gate spacer to form a diffusion area.

13. The method of claim 12, wherein the trap area has a width of approximately 0.1 μm to 0.15 μm.

14. The method of claim 12, wherein a depth of the trap area is larger than that of the channel layer.

15. The method of claim 12, wherein the trap area has a depth of approximately 20 nm to 80 nm.

16. The method of claim 12, wherein the channel layer has a depth of approximately 20 nm to 50 nm.

17. The method of claim 12, wherein the epi-layer is of a P-type.

18. The method of claim 12, wherein the channel layer is of a P-type.

19. The method of claim 12, wherein the diffusion area is formed by implanting n+-type dopant ions into the epi-layer located at sides of the gate spacer.

20. The method of claim 12, wherein forming the epi-layer, channel layer, gate insulating film, gate electrode, gate spacer, diffusion area, and trap area are part of a process of forming a reset transistor in a CMOS image sensor.
